(19) United States
(12) Patent Application Publication
(10) Pub. No.: US 2026/0334116 A1
(43) Pub. Date: Oct. 22, 2026

(54) METHODS OF TUNING A FILM AND RELATED SYSTEMS FIELD

(71) Applicant: ASM IP Holding B.V., Almere (NL)

(72) Inventors: Petro Deminskyi, Espoo (FI); Vivek Koladi Mootheri, Leuven (BE)

(21) Appl. No.: 19/650,735

(22) Filed: Apr. 17, 2026

Related U.S. Application Data
(60) Provisional application No. 63/792,475, filed on Apr. 22, 2025.

(51) Int. Cl. H10P 32/20; H10P 14/40; H10P 14/43; H10P 14/60; H10P 32/30; H10P 70/00

(52) U.S. Cl. CPC H10P 32/20; H10P 14/414; H10P 14/43; H10P 14/6339; H10P 32/30; H10P 70/23

(57) ABSTRACT

A method of tuning a film. The method includes placing a substrate with the film thereon in a reaction chamber equipped with a hot wire element. The method includes contacting a gas with the hot wire element to generate one or more radical species. The method includes tuning the properties of the film by exposing the film to one or more radical species.

### CROSS-REFERENCE TO RELATED APPLICATIONS

This application claims priority to U.S. Provisional Patent Application Ser. No. 63/792,475 filed Apr. 22, 2025 titled METHODS OF TUNING A FILM AND RELATED SYSTEMS FIELD, the disclosure of which is hereby incorporated by reference in its entirety.

### FIELD

The present disclosure relates to semiconductor technology, and in particular, it relates to a method of tuning a threshold voltage adjusting film with a hot wire system.

### BACKGROUND

Transistors are integrated circuit components or elements that are often formed on a semiconductor substrate. Specifically, modern integrated circuits incorporate field-effect transistors (FETs) in which current flows through a semiconducting channel between a source and a drain, in response to a voltage applied to a control gate. The scaling of semiconductor devices, such as, for example, complementary metal-oxide-semiconductor (CMOS) devices, has led to significant improvements in speed and density of modern integrated circuits. In advanced CMOS devices, including central processing unit (CPU) and system-on-a-chip (SoC), structures with multiple threshold voltages are needed in order to optimize delay or power consumption. However, as device dimensions have shrunk, providing highly functional structures with multiple threshold voltages is facing serious challenges. For instance, one particular problem is controlling the threshold voltage of FETs. Therefore, there is a need to develop alternative materials to achieve better performance while scaling down.

Any discussion, including discussion of problems and solutions, set forth in this section has been included in this disclosure solely for the purpose of providing a context for the present disclosure. This discussion should not be taken as an admission that any or all of the information was known at the time the invention was made or otherwise constitutes prior art.

### BRIEF SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

In accordance with one or more embodiments, methods for of tuning a film are disclosed, the methods including: providing a substrate with the film thereon in a reaction chamber equipped with a hot wire element, contacting a gas with the hot wire element to generate one or more radical species, and tuning properties of the film by exposing the film to the one or more radical species.

In some embodiments, the gas includes O₂, H₂, H₂S, PH₃, N₂, He, Ar, Kr, Xe, or a combination thereof.

In some embodiments, the film is a dipole film, a high-k film, or a work function metal film used for threshold voltage adjustment in a gate stack.

In some embodiments, the film includes rare earth or transitional metal oxide, rare earth or transitional metal nitride, rare earth or transitional metal silicate, rare earth or transitional metal silicide, rare earth or transition metal sulfide, rare earth or transition metal boride, rare earth or transition metal phosphide, rare earth or transition metal selenides, rare earth or transition metal tellurides, or a combination thereof.

In some embodiments, the tuning includes cleaning the film by removing the impurities from the film.

In some embodiments, cleaning the film by removing the impurities from the film includes: reacting the one or more radical species with the impurities in the film to form volatile molecules that evaporate from the film.

In some embodiments, the impurities comprise oxygen and the volatile molecules comprise dihydrogen monoxide (H₂O) molecules.

In some embodiments, the impurities comprise carbon and the volatile molecules comprise carbon dioxide (CO₂) molecules.

In some embodiments, the tuning includes doping the one or more radical species into the film as property-tuning impurities.

In some embodiments, the one or more radical species includes hydrogen radicals, sulfur radicals, or a combination thereof.

In some embodiments, doping the one or more radical species into the film removes excess oxygen from the film.

In some embodiments, the tuning includes tuning the elemental contents of the film.

In some embodiments, the properties of the film comprise physical, chemical, electrical, and surface properties, crystal phase, dipole phase, dielectric constant, work function, resistivity, capacitance equivalent thickness, current leakage, or a combination thereof.

In some embodiments, the hot wire element is heated to a temperature ranging from 450 °C to 2200 °C while contacting with the gas.

In some embodiments, a thickness of the film ranges from 1 nm to 4 nm.

In some embodiments, tuning the film is performed before a high-k material deposition process.

In some embodiments, tuning the film is performed after a high-k material deposition process.

In some embodiment, the film is deposited by atomic layer deposition (ALD) and the tuning is performed after a final cycle of the ALD.

In some embodiments, the film is deposited by at least one ALD cycle and at least another ALD cycle is performed after the tuning.

In some embodiment, a reactor system is disclosed and is configured to carry out the methods disclosed herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWINGS

The present invention can be more fully understood by reading the subsequent detailed description and examples with references made to the accompanying drawings, wherein: It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 is a flowchart of a method of tuning a film on a substrate according to some embodiments of the present disclosure;

FIG. 2 is a schematic view of structure in accordance with step 14 of providing a substrate and step 16 of introducing tuning gas in FIG. 1 according to some embodiments of the present disclosure.

FIG. 3 is a schematic view of structure in accordance with the step of performing the removal process in FIG. 1 according to some embodiments of the present disclosure.

FIG. 4 is a schematic view of structure in accordance with step 14 of providing a substrate and step 16 of introducing tuning gas in FIG. 1 according to some other embodiment of the present disclosure.

FIG. 5 is a schematic view of structure in accordance with step 14 of providing a substrate and step 16 of introducing tuning gas in FIG. 1 according to some other embodiment of the present disclosure.

FIG. 6 is a flowchart of a method of tuning a film on a substrate according to some other embodiment of the present disclosure;

FIG. 7 is a schematic view of a system used to perform a method described herein according to some embodiments of the present disclosure.

### DETAILED DESCRIPTION

The following description is made for the purpose of illustrating the general principles of disclosure and should not be taken in a limiting sense. The scope of the disclosure is determined by reference to the appended claims. Reference will now be made in detail to exemplary embodiments of the present disclosure, examples of which are illustrated in the accompanying drawings. Whenever possible, the same reference numbers are used in the drawings and descriptions to refer to the same or similar parts.

As set forth in more detail below, various embodiments of the disclosure provide methods for forming structures, such as gate dielectrics or portions thereof for field effect transistors. Exemplary methods can be used to, for example, form CMOS devices, or portions of such devices. However, unless noted otherwise, the invention is not necessarily limited to such examples.

The term “threshold voltage shifting layer” as used herein refers to a layer which is useful for controlling the threshold voltage of a metal oxide field effect transistor. It may be equivalent to similar terms such as “threshold voltage tuning layer,” “dipole layer,” or “threshold voltage controlling layer.” The term “threshold voltage shifting layer” as used herein may be simply referred to as “layer.”

As used herein, the term “work function metal film” may refer to any conductive metal-containing material that produces a suitable effective work function when formed in, on, or over a gate dielectric of a semiconductor device.

In the disclosure, the terms “about”, “equal to”, “equal” or “the same”, “substantially” or “approximately” usually indicate a value of a given value or range that varies within 20%, or a value of a given value or range that varies within 10%, within 5%, or within 3%, or within 2%, or within 1%, or within 0.5%. Further, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like.

As used herein, the term “precursor” can refer to a compound that participates in the chemical reaction that produces another compound. In this disclosure, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may include material or a layer with pinholes and/or isolated islands. A film or layer may be at least partially continuous. A film or layer may be patterned, e.g., subdivided, and may be included in a plurality of semiconductor devices.

In this disclosure, the term “deposition process” as used herein can refer to the introduction of precursors into a reaction chamber to deposit a layer over a substrate. The term “cyclical deposition process” can refer to a sequential introduction of precursors into a reaction chamber to deposit a layer or a film over a substrate and includes processing techniques such as atomic layer deposition (ALD), cyclical chemical vapor deposition (cyclical CVD), and hybrid cyclical deposition processes that include an ALD and a CVD.

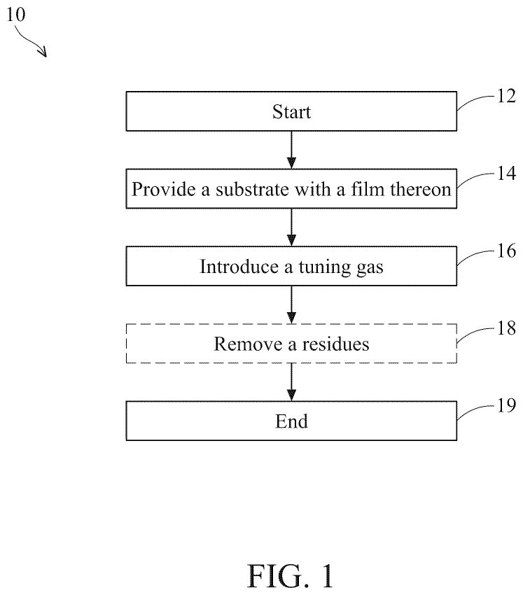

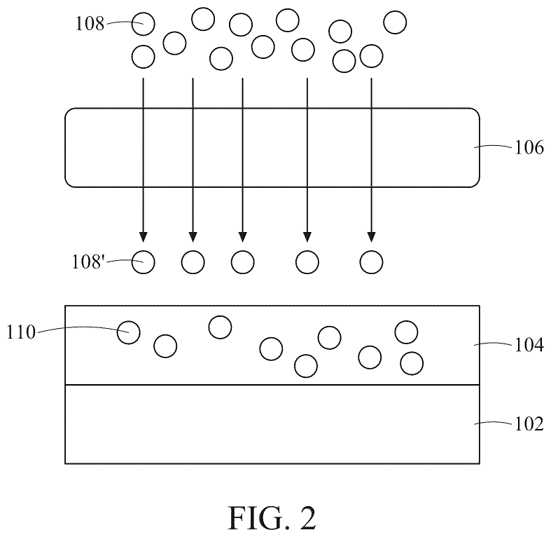

In general, the disclosure is directed to a technology utilizing a system (e.g., reaction chamber) equipped with a hot wire element for tuning a film. One aspect of the present disclosure is providing a method of tuning a film on a substrate. FIG. 2 is a schematic view of structure in accordance with step 14 of providing a substrate and step 16 of introducing tuning gas in FIG. 1 according to some embodiments of the present disclosure. As illustrated in FIG. 1, the method 10 includes step 14 of providing a substrate with film thereon and step 16 of introducing tuning gas. As illustrated in FIG. 1, the method 10 further includes optional step 18 of removing the residues using an additional process in some embodiments.

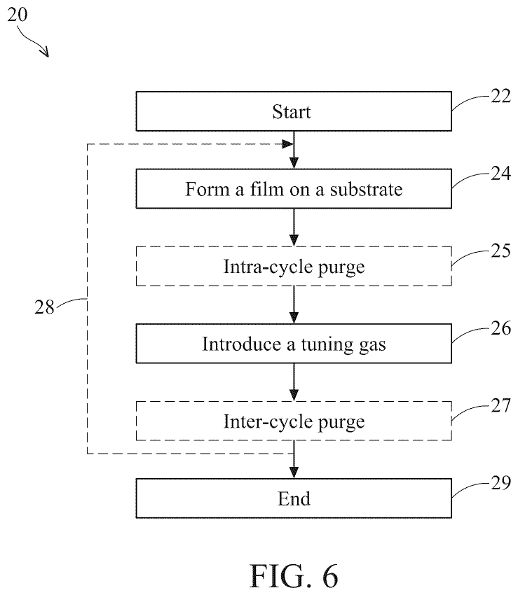

It should be understood that method 10 illustrated in FIG. 1 is merely exemplary and is not intended to limit the present disclosure. Additional steps may be provided before, during, and after method 10. In addition, method 10 may be modified to be performed in other suitable manners. For example, in some embodiments, a similar method may be integrated into a cyclic process, as will be described in detail later in FIG. 6.

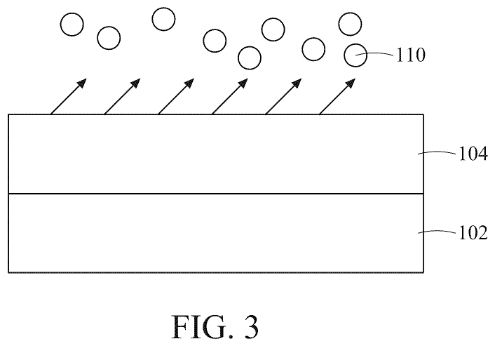

FIG. 2 is a schematic view of structure in accordance with the step of introducing the tuning gas in FIG. 1 according to some embodiments of the present disclosure. FIG. 3 is a schematic view of structure in accordance with the step of performing the removal process in FIG. 1 according to some embodiments of the present disclosure. FIGS. 2 and 3 illustrate some embodiments of utilizing a hot wire-assisted configuration to clean or remove the impurities from the film 104 on the substrate 102.

Referring to FIGS. 1 and 2, method 10 starts (12) with step 14 of providing substrate 102 with a film 104 thereon. More specifically, substrate 102 with a film 104 thereon is provided in a reaction chamber (not explicitly shown) equipped with (or coupled with) a hot wire system 106, as illustrated in FIG. 2.

The substrate 102 may include any suitable materials. As mentioned above, substrate 102 may include a bulk material, such as silicon (e.g., single-crystal silicon), other Group IV materials, such as germanium, or other semiconductor materials, such as Group II-VI or Group III-V semiconductor materials, and may include one or more layers overlying or underlying the bulk material.

The film 104 in these embodiments may be a film that allows threshold voltage adjustment in a gate stack. For example, film 104 may be a dipole film or a work-function metal film in some embodiments.

As used herein, the term “dipole layer” in a gate stack refers to a layer where a net dipole moment is established at or near the surface or interface of the semiconductor material. It is created by introducing (e.g., depositing) a different material, typically a dielectric, onto the surface or interface. A dielectric is an electrical insulator that can be polarized by an applied electric field. Additionally, or alternatively, the dielectric surface can comprise a high-κ dielectric surface (i.e., high dielectric constant compared to silicon oxide). The dipole layer results from a charge redistribution (i.e., polarization), causing positive charges to accumulate on one side and negative charges on the other. The polarizability of a dipole layer has significant effects on the semiconductor structure and thus is widely used in property tuning, such as threshold voltage or work function control.

In the embodiments where film 104 is a dipole layer, the material of film 104 may be a suitable rare earth-containing film or transition metal-containing film. For example, the material of film 104 in these embodiments includes rare earth or transitional metal oxide, rare earth or transitional metal nitride, rare earth or transitional metal silicate, rare earth or transitional metal silicide, rare earth or transition metal sulfide, rare earth or transition metal boride, rare earth or transition metal phosphide, rare earth or transition metal selenides, rare earth or transition metal tellurides, or a combination thereof. In these embodiments where film 104 is a dipole layer, the thickness of film 104 may be small enough to achieve the desired work function. For example, the thickness of film 104 ranges from 1 nm to 4 nm in the embodiments of this disclosure.

Referring to FIGS. 1 and 2, method 10 proceeds to step 16 of introducing tuning gas. Although not illustrated with figures, the tuning gas 108 is introduced into the reaction chamber into which substrate 102 is placed in the actual operation. As illustrated in FIG. 2, tuning gas 108 is made to come into contact with the hot wire system 106 by flowing through the hot wire system 106 and is then turned into free radical species 108′ by receiving energy from the hot wire system 106. In these embodiments, the hot wire system 106 includes one or more elongated tube-type heating elements, such as tungsten filament. The hot wire system 106 is heated to the desired temperature, enabling the tuning gas 108 to be turned into excited free radical species as it flows through and contacts with the hot wire system 106. In some embodiments, this desired temperature is set to supply the gas with the energy needed for various applications. In some embodiments, this temperature is related to the proportion of tuning gas 108 that is turned into excited free radical species. In some embodiments, the temperature of the hot wire system 106 ranges from 450 °C to 2200 °C while in contact with the tuning gas 108 in some embodiments.

In some embodiments, tuning gas 108 may be selected based on its intended function. For example, tuning gas 108 may include O₂, H₂, H₂S, PH₃, N₂, He, Ar, Kr, Xe, or a combination thereof in some embodiments. However, the disclosure is not limited hereto. The tuning gas 108 may also be other suitable gases in other embodiments.

As illustrated in FIG. 2, the tuning gas 108 flows through and contacts with the heated hot wire system 106 resulting in free radical species 108′. The free radical species 108′ flows into the reaction chamber, enabling film 104 on substrate 102 to be exposed to the free radical species 108′. As illustrated in FIG. 2, the resulting free radical species 108′ flows into film 104 and reacts with the impurities in the film 104 to form one or more molecules 110. In these embodiments, molecule 110 is volatile and may be removed in step 18 by heating the substrate 102 to evaporate it, optionally in combination with a purge process.

The species of tuning gas 108 may be selected based on the impurities to be removed from the film 104. In one embodiment, the tuning gas 108 is H₂, it flows through the heated hot wire system 106 and results in a hydrogen radical 108′. The hydrogen radical 108′ then flows into film 104, reacting with oxygen impurities in film 104 and forming a dihydrogen monoxide (H₂O) molecule 110. The H₂O molecule 110 is then removed in step 18. In another embodiment, the tuning gas 108 is O₂, which flows through the heated hot wire system 106 and results in oxygen radical 108′. The oxygen radical 108′ then flows into film 104, reacting with carbon impurities in film 104 and forming a carbon dioxide (CO₂) molecule 110. The CO₂ molecule 110 is then removed in step 18.

Referring to FIGS. 1 and 3, the substrate 102 is heated and an optional purge process may be performed in step 18 to remove the formed molecule 110 from the film 104. As a result, the impurities in film 104 (e.g., excess oxygen or carbon impurities) are removed by combining them with a free radical species, which is generated by bringing the desired gas into contact with the hot wire system.

It is worth noting that utilizing a hot wire-assisted approach for cleaning impurities on film in this disclosure provides a more effective solution for removing impurities and also reduces the side effects. This can generally be attributed to the manner of free radical species generation. It is believed that thermally generated radicals in a hot wire-assisted approach have superior lifetime and reactivity compared to plasma-generated radicals because they form without ionization, reducing recombination losses. This stability of thermally generated radicals allows for a higher concentration of reactive species, leading to an improved process control compared to plasma-generated radicals.

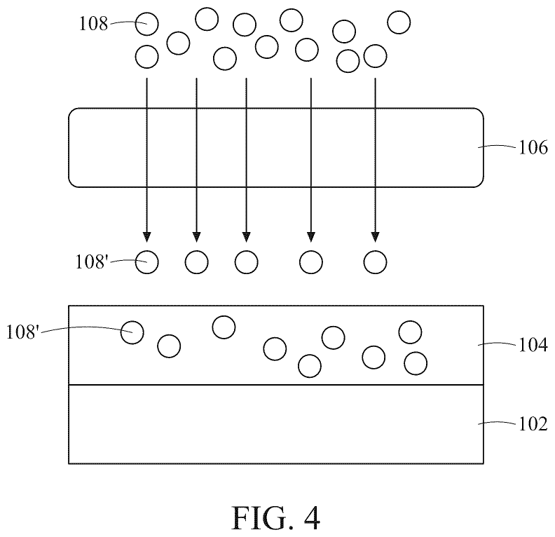

FIG. 4 is a schematic view of structure in accordance with step 14 of providing a substrate and step 16 of introducing tuning gas in FIG. 1 according to some other embodiment of the present disclosure. FIG. 4 illustrates some other embodiments of utilizing a hot wire-assisted configuration to introduce a substance into film 104 on substrate 102. Unless otherwise stated, elements in FIG. 4 that have the same numeral reference as those in FIG. 2 represent the same elements.

Referring to FIG. 4, the configuration of the embodiments illustrated in FIG. 4 is similar to the embodiments illustrated in FIGS. 2 and 3, except that the embodiments illustrated in FIG. 4 intend to introduce the free radical species generated by the hot wire system 106 into film 104. In those embodiments illustrated in FIG. 4, different types of processes may be implemented by adjusting the hot wire system 106 (e.g., adjusting the temperature of hot wire system 106 to control the energy of the gas and/or free radical species).

In some embodiments, the process may be a doping process, in which free radical species 108′ serves as property-tuning impurities or property-tuning dopants. In these embodiments, doping free radical species 108′ into film 104 removes excess oxygen from the film 104. In these embodiments, doping free radical species 108′ into film 104 tunes the bulk properties of film 104, such as crystal phase, dipole phase, dielectric constant, resistivity, capacitance equivalent thickness, or a combination thereof. In some other embodiments, the process may be a treatment process, in which free radical species 108′ are used to modify the properties on or near the surface of film 104, such as work function, capacitance equivalent thickness, and current leakage. However, both embodiments of doping and treating may be used for tuning the elemental contents of the film 104.

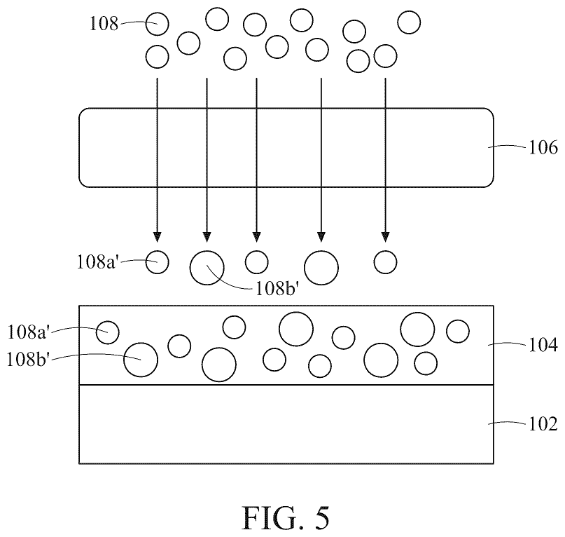

FIG. 5 is a schematic view of structure in accordance with step 14 of providing a substrate and step 16 of introducing tuning gas in FIG. 1 according to some other embodiment of the present disclosure. In some embodiments, tuning gas 108 may be homonuclear molecules, such as hydrogen (H₂) or nitrogen (N₂), which are converted into the same free radical species by the hot wire system 106 as illustrated in FIG. 4. In some other embodiments, tuning gas 108 may be heteronuclear molecules, such as hydrogen sulfide (H₂S) or phosphine (PH₃), which are converted into different free radical species by the hot wire system 106 as illustrated in FIG. 5. For example, tuning gas 108 in embodiments illustrated in FIG. 5 may be hydrogen sulfide (H₂S). The hydrogen sulfide (H₂S) may be converted into hydrogen radicals 108a′ and sulfur radicals 108b′ when flowing through, and being in contact with, the hot wire system 106.

FIG. 6 is a flowchart of a method of tuning a film on a substrate according to some other embodiment of the present disclosure. Referring to FIG. 1, in some embodiments, the step of forming film 104 on substrate 102 and the step of introducing the tuning gas for tuning the film 104 may be performed sequentially. That is, the step of tuning the film is performed only after film 104 is fully formed on substrate 102, with no further steps of forming the film 104 once the tuning step begins in these embodiments. In these embodiments, film 104 may be deposited on substrate 102 by a cyclic atomic layer deposition (ALD) process, and the tuning step is performed only after the final cycle of the cyclic ALD process. In these embodiments, the tuning step for film 104 (e.g., in step 16 of introducing tuning gas in FIG. 1) is performed only once after the step of forming film 104 is completed, after which method 10 ends (19).

Referring to FIGS. 4 and 6, in some other embodiments, as illustrated in FIG. 6, forming film 104 and introducing tuning gas for tuning film 104 may be performed by turn in method 20. In other words, the steps of forming film 104 and tuning film 104 may cyclically take place in these embodiments. As illustrated in FIG. 6, step 26 of introducing tuning gas may be performed after step 24 of forming a film on the substrate has been completed at least once. In these embodiments, an optional intra-cycle purging step 16 may be performed between steps 14 and 17, and an optional inter-cycle purging step 20 may be performed after step 16. As illustrated in FIG. 6, the sequence including step 24 of forming a film on the substrate, step 26 of introducing tuning gas, and optional purging steps 25 and 27 may be repeated (28) any number of times to obtain film 104 with a desired thickness.

Although not illustrated, the steps of tuning the film 104 in the embodiments illustrated in FIG. 1 and FIG. 6 may be performed before or after a high-k material deposition process in an actual gate stack process. That is, the tuning step described herein may be applied to the film below the high-k material layer or the film above the high-k material layer in an actual gate stack process.

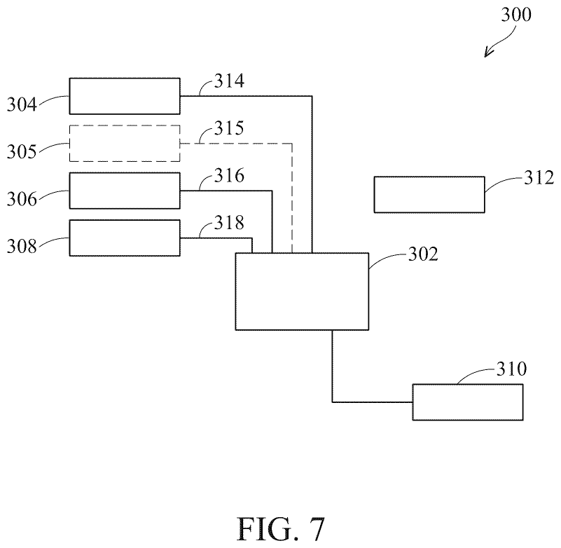

FIG. 7 is a schematic view of a system used to perform the method described herein according to some embodiments of the present disclosure. Referring to FIG. 7, in the example illustrated in FIG. 7, system 300 includes a reaction chamber 302, a metal precursor gas source 304, a tuning gas source 306, a purge gas source 308, an exhaust 310, and a controller 312. In some embodiments, system 300 further includes another gas source, such as an oxygen reactant gas source 305.

During operation of system 300, a substrate (e.g., substrate 102 as described in previous embodiments) is provided in the reaction chamber 302. In some embodiments, the substrate is provided in reaction chamber 302 with a film formed thereon (such as those embodiments illustrated in FIG. 1). In these embodiments, once the substrate is provided in reaction chamber 302, the gas from tuning gas source 306 and purge gas source 308 are introduced into the reaction chamber 302. In other embodiments which steps of forming a film on the substrate and tuning the film are carried out in cyclic (such as those embodiments illustrated in FIG. 6). The substrate is provided in reaction chamber 302 then the gas from the metal precursor gas source 304, tuning gas source 306, and purge gas source 308 (optionally from oxygen reactant gas source 305) are introduced into the reaction chamber 302.

The reaction chamber 302 may include any suitable reaction chamber, such as an ALD reaction chamber. The metal precursor gas source 304 may include a vessel and one or more precursors used for forming a film on a substrate (e.g., forming film 104 on substrate 102). The tuning gas source 306 may include a vessel and one or more of the tuning gases described herein-alone or mixed with one or more carrier (e.g., inert) gases. The purge gas source 308 may include one or more inert gases, such as N₂ or a noble gas. These gas sources (304, 305, 306, and 308) may be coupled to the reaction chamber 302 via lines 314, 315, 316, and 318. The lines 314, 315, 316, and 318 may each include flow controllers, valves, heaters, and the like. The exhaust 310 may include one or more vacuum pumps.

The controller 312 includes electronic circuitry and software to selectively operate valves, manifolds, heaters, pumps, and other components included in system 300. Such circuitry and components operate to introduce precursors, reactants, and purge gases from the respective sources (304, 305, 306, and 308). The controller 312 may control the timing of gas pulse sequences, the temperature of the substrate and/or reaction chamber, the pressure within the reaction chamber, and various other operations to provide proper operation of the system 300. The controller 312 may include control software to electrically or pneumatically control valves to control the flow of precursors and reactants (i.e., nitrogen reactants and/or oxygen reactants) and purge gases into and out of the reaction chamber 302. The controller 312 may include modules such as a software or hardware component, e.g., an FPGA or ASIC, which perform certain tasks. A module can advantageously be configured to reside on the addressable storage medium of the control system and be configured to execute one or more processes.

Although embodiments of the present disclosure and the advantages thereof have been disclosed as described above, it should be understood that changes, substitutions, and modifications may be made without departing from the spirit and scope of the disclosure. In addition, the protection scope of the present disclosure is not limited to the processes, machines, fabrications, compositions, devices, methods, and steps in the specific embodiments described in the specification. According to the embodiments of the present disclosure, a person of ordinary skill in the art may understand that current or future processes, machines, fabrications, compositions, devices, methods, and steps capable of performing substantially the same functions or achieving substantially the same results may be used in the embodiments of the present disclosure. Therefore, the protection scope of the present disclosure includes the above-mentioned processes, machines, fabrications, compositions, devices, methods, and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

What is claimed is:

1. A method of tuning a film, comprising:
providing a substrate with the film thereon in a reaction chamber equipped with a hot wire element;
contacting a gas with the hot wire element to generate one or more radical species; and
tuning properties of the film by exposing the film to the one or more radical species.

2. The method of claim 1, wherein the gas includes O₂, H₂, H₂S, PH₃, N₂, He, Ar, Kr, Xe, or a combination thereof.

3. The method of claim 1, wherein the film is a dipole film, a high-k film, or a work function metal film used for threshold voltage adjustment in a gate stack.

4. The method of claim 1, wherein the film includes rare earth or transitional metal oxide, rare earth or transitional metal nitride, rare earth or transitional metal silicate, rare earth or transitional metal silicide, rare earth or transition metal sulfide, rare earth or transition metal boride, rare earth or transition metal phosphide, rare earth or transition metal selenides, rare earth or transition metal tellurides, or a combination thereof.

5. The method of claim 1, wherein the tuning includes cleaning the film by removing impurities from the film.

6. The method of claim 5, wherein cleaning the film by removing the impurities from the film includes:
reacting the one or more radical species with the impurities in the film to form volatile molecules that evaporate from the film.

7. The method of claim 6, wherein the impurities comprise oxygen and the volatile molecules comprise dihydrogen monoxide (H₂O) molecules.

8. The method of claim 6, wherein the impurities comprise carbon and the volatile molecules comprise carbon dioxide (CO₂) molecules.

9. The method of claim 1, wherein the tuning includes doping the one or more radical species into the film as property-tuning impurities.

10. The method of claim 9, wherein the one or more radical species includes hydrogen radicals, sulfur radicals, or a combination thereof.

11. The method of claim 9, wherein doping the one or more radical species into the film removes excess oxygen from the film.

12. The method of claim 1, wherein the tuning includes tuning elemental contents of the film.

13. The method of claim 1, wherein the properties of the film comprise physical, chemical, electrical, and surface properties, crystal phase, dipole phase, dielectric constant, work function, resistivity, capacitance equivalent thickness, current leakage, or a combination thereof.

14. The method of claim 1, wherein the hot wire element is heated to a temperature ranging from 450 °C to 2200 °C while contacting with the gas.

15. The method of claim 1, wherein a thickness of the film ranges from 1 nm to 4 nm.

16. The method of claim 1, wherein tuning the film is performed before a high-k material deposition process.

17. The method of claim 1, wherein tuning the film is performed after a high-k material deposition process.

18. The method of claim 1, wherein the film is deposited by atomic layer deposition (ALD) and the tuning is performed after a final cycle of the ALD.

19. The method of claim 1, wherein the film is deposited by at least one ALD cycle and at least another ALD cycle is performed after the tuning.

20. A reactor system, configured to carry out the method of claim 1.
